(19) United States
(12) Patent Application Publication
(10) Pub. No.: US 2019/0129229 A1
(43) Pub. Date: May 2, 2019

(54) NARROW FRAME DISPLAY PANEL AND DISPLAY DEVICE

(71) Applicant: WUHAN CHINA STAR CPTOELECTRONICS TECHNOLOGY CO., LTD, Wuhan, Hubei (CN)

(72) Inventors: Hongqing CUI, Wuhan, Hubei (CN); Dejiun LI, Wuhan, Hubei (CN); Po-hua LUNG, Wuhan, Hubei (CN); Wenqing SONG, Wuhan, Hubei (CN)

(21) Appl. No.: 15/740,421

(22) PCT Filed: Nov. 14, 2017
(86) PCT No.: PCT/CN2017/110772

§ 371 Date: Oct. 18, 2018

(30) Foreign Application Priority Data
Oct. 31, 2017 (CN) 201711043755.X

(51) Int. Cl. G02F 1/1333; G02F 1/1362; G02F 1/1335; H05K 1/18

(52) U.S. Cl. CPC G02F 1/133308; G02F 1/136209; G02B 6/0055; G02F 1/133514; H05K 1/189; G02F 1/133512

(57) ABSTRACT

The disclosure discloses a narrow frame display panel, comprising an array substrate, a color film substrate, a liquid crystal filled between the array substrate and the color film substrate, a flexible circuit board and a driving chip, wherein a side located by the array substrate is a light-exiting surface, and one end of the array substrate is a bonding end; one end of the flexible circuit board is bound to a surface of the bonding end facing the color film substrate, and the other end of the flexible circuit board is bound with a driving chip and arranged opposite to the color film substrate after being bent away from the light-exiting surface, and the driving chip is located on the side of the flexible circuit board facing away from the color film substrate. The disclosure further discloses a display device.

### RELATED APPLICATIONS

The present application is a National Phase of International Application Number PCT/CN2017/110772, filed Nov. 14, 2017, and claims the priority of China Application No. 201711043755.X, filed Oct. 31, 2017.

### BACKGROUND OF THE INVENTION

### 1. Field of the Invention

The disclosure relates to a display technical field, and more particularly to a narrow frame display panel and a display device.

### 2. The Related Arts

At present, the popularity of full-screen mobile phones is getting higher and higher, and the screen with high screen proportion is getting more and more popular. As a result, a lot of narrow frame solutions are created, and the narrow frame solutions mainly aim at the left and right frames, but regarding to the mobile phones, raising the proportion of screen-to-body ratio to the lower frame is a big topic. The so-called screen-to-body ratio is the ratio of the screen area to the mobile phones area. A higher proportion of the screen-to-body ratio may bring a better visual experience to the user. The flexible OLED display screen is a key element capable of achieving the hyperbolic design currently. With the increasingly mature of the flexible OLED technology, industrial design and physical form of the mobile phones in the future are bound to occur more innovation and changes.

Therefore, many manufacturers have adopted a COF (chip on film) scheme of a lower frame of the display reducing the width of the lower frame and improving the screen ratio compared with the conventional chip on glass (COG) design. However; the COF scheme also has many problems. For example; a chip (IC) is bonded to a flexible printed circuit (FPC), so that the space occupied by the frame for bonding the chip may be saved, resulting in a narrower lower frame. When the entire FPC is bent, the chip is located on the lower surface of the backlight module and directly opposite to a reflection sheet. Since the chip is formed as a protrusion with a certain height, a spacer is needed to avoid direct contact with the reflection sheet to cause damages to both of them. However, if the chip is a heat source and close to the reflector, it may easily cause an optical quality of the backlight module. At the same time, the thickness of the display may increase greatly due to the spacer.

### SUMMARY

In view of the shortcomings of the prior art, the disclosure provides a narrow frame display panel and a display device, so as to reduce the width of the frame and improve the screen-to-body ratio while ensuring the optical quality of the backlight module without significantly increasing the thickness of the display device.

In order to achieve the above objects, the disclosure adopts the following technical schemes.

A narrow frame display panel, including an array substrate, a color film substrate, a liquid crystal filled between the array substrate and the color film substrate, a flexible circuit board and a driving chip, wherein a side located by the array substrate is located is a light-exiting surface, and one end of the array substrate is a bonding end; one end of the flexible circuit board is bound to a surface of the bonding end facing the color film substrate, and the other end of the flexible circuit board is bound with a driving chip and arranged opposite to the color film substrate after being bent away from the light-exiting surface, and the driving chip is located on the side of the flexible circuit board facing away from the color film substrate.

As an embodiment, the flexible circuit board is a single-layered chip-on-film, and the bonding end and the driving chip are simultaneously turned on the same side of the single-layered chip-on-film.

As an embodiment, an outer surface of the array substrate is covered with a hollow black shielding layer, and the black shielding layer completely shields metal electrodes in an inner surface of the array substrate.

As an embodiment, a black matrix is arranged in an inner surface of the color film substrate, and a projection of the black shielding layer on the color film substrate completely covers the black matrix.

Another object of the disclosure is to provide a display device, wherein the display device includes a backlight module and a narrow frame display panel, the backlight module is on the side of the color film substrate.

As an embodiment, the backlight module includes a reflection sheet, a light guide plate, a set of an optical film and a light source from bottom to top, the light source is arranged on the light guide plate and provides a backlight for the light guide plate, and a projection of the light source in a direction perpendicular to the reflection sheet is located in the reflection sheet.

As an embodiment, the display device further includes a plastic frame, the light source including a substrate and LED lamp beads arranged on the surface of the substrate, the plastic frame arranged on the reflection sheet and arranged spaced from the light guide plate, wherein the LED lamp beads are arranged in a gap between the plastic frame and the light guide plate, and two ends of the substrate are respectively attached to the upper surface of the light guide plate and the plastic frame.

As an embodiment, the display device further includes a light-shielding sheet, the light-shielding sheet being attached to an upper surface of the substrate and extending to partially cover an edge of the set of an optical film.

As an embodiment, the display device further includes a middle frame, a groove is formed in the inner surface of the middle frame, the flexible circuit board is directly opposite to the middle frame, and the driving chip is housed in the groove.

In the disclosure, one end of a flexible circuit board is bound to a surface of the bonding end facing the color film substrate, the other end of the flexible circuit board is bound with a driving chip and arranged opposite to the color film substrate after being bent away from the light-exiting surface. Thus the flexible circuit board may not be seen outside the display panel. Therefore, the width of the frame may be reduced and the screen-to-body ratio may be increased. Meanwhile, the driving chip is located on a side of the flexible circuit board facing away from the color film substrate, and therefore may be away from the heated reflection sheet of the backlight module, and this ensures an optical quality without increasing the thickness of the display device. In addition, the black shielding layer on the outer surface of the array substrate may prevent the ambient light from illuminating metal electrodes on the inner surface of the array substrate to prevent specular reflection.

### BRIEF DESCRIPTION OF THE DRAWINGS

FIG. 1 is a schematic structural diagram of a narrow frame display panel according to an embodiment of the disclosure;

FIG. 2 is a schematic structural diagram of a display device according to an embodiment of the disclosure.

### DETAILED DESCRIPTION OF THE PREFERRED EMBODIMENTS

In order to make the objectives, technical schemes and advantages of the disclosure more comprehensible, the disclosure is further described in detail below with reference to the accompanying drawings and embodiments. It should be understood that the specific embodiments described herein are merely used to explain the disclosure, and are not intended to limit the disclosure.

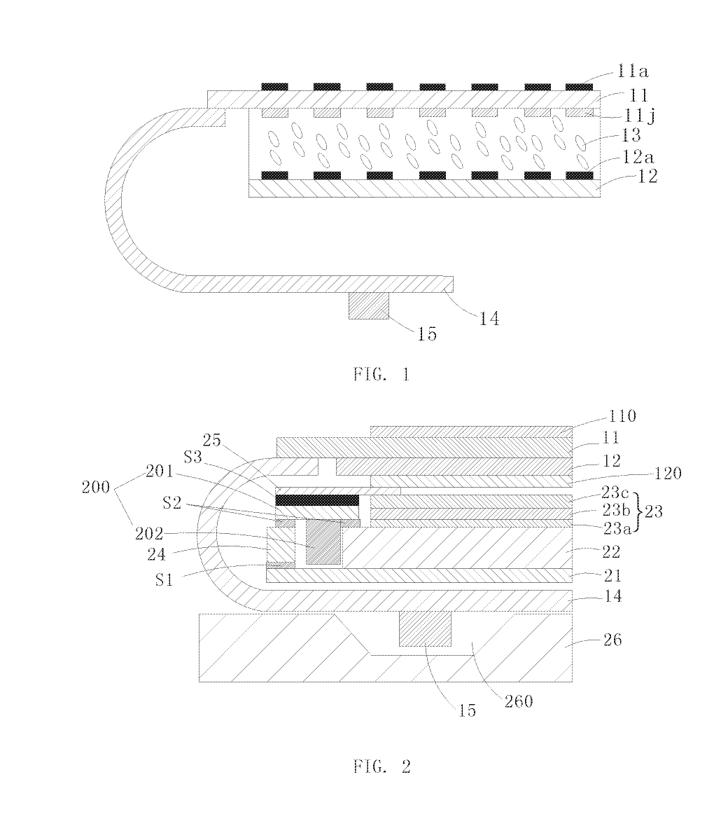

Refer to FIGS. 1 and 2, a narrow frame display panel according to an embodiment of the disclosure mainly includes an array substrate 11 and a color film substrate 12 arranged opposite to each other, a liquid crystal 13 filled between the array substrate 11 and the color film substrate 12, a flexible circuit board 14 and a driving chip 15. Different from the conventional display panel, a side located by the array substrate 11 in this embodiment is a light-exiting surface and a backlight source enters light from the side the color film substrate 12 located. The upper polarizer 110 and the lower polarizer 120 are respectively attached to outer surfaces of the array substrate 11 and the color film substrate 12. The backlight light enters into the liquid crystal 13 after being deflected by the lower polarizer 120, and is deflected by the upper polarizer 110 again and then emits.

Compared with the color film substrate 12, one end of the array substrate 11 is relatively longer, and an edge portion of the end located outside the non-display area serves as a binding end. One end of the flexible circuit board 14 is bound to a surface of the binding end facing the color film substrate 12 (i.e., a lower surface as shown in FIG. 1). The other end of the flexible circuit board 14 is bound with a driving chip 15 and arranged opposite to the color film substrate 12 after being bent away from the light-exiting surface. After the flexible circuit board 14 is bent, the driving chip 15 is located on the side of the flexible circuit board 14 facing away from the color film substrate 12. Therefore, after light guide plates and reflection sheets and the like of the backlight module are assembled between the color film substrate 12 and the flexible circuit board 14, the driving chip is away from the reflection sheet of the backlight module, ensuring the optical quality, and at the same time avoiding a heated driving chip affecting the heat dissipation of the reflection sheet.

In the conventional technology, if the side where the color film substrate 12 is located is still used as the light-exiting surface of the display panel, a lower surface of one end of the flexible circuit board 14 needs to be bound to the binding end of the array substrate 11, and the driving chip 15 is needed to be bound to a upper surface of the other end of the flexible circuit board 14, so as to ensure the driving chip 15 being away from the reflection sheet after the end where the driving chip 15 is located being bent, so as to cause the flexible circuit board 14 needs at least two layers of chip on film to be pressed without an advantageous cost. In addition, the binding end faces the viewer. Therefore, it is necessary to make the front cover for shielding to achieve aesthetics, and it is very difficult to achieve the narrowing of a frame of the bonding end. In the embodiment, since the bonding end and the driving chip 15 are simultaneously turned on with the same surface of a single-layered chip on film, the flexible circuit board 14 may use a single-layered chip on film (COF), thereby the cost may be greatly reduced, and the optical quality may also be ensured, at the same time, of the real frame-less design may be achieved at the side where the binding side is located.

After the array substrate 11 being formed outer side, the front frame may be omitted to achieve a real frame-less design. However, since an inner surface of the array substrate 11 is coated with various metal electrodes 11j, when the flexible circuit board 14 is bound to the inner side, when viewing the picture, the metal electrodes in the outer array substrate 11 reflects the ambient light and affects the viewing effect. Based on this, in this embodiment, the outer surface of the array substrate 11 is further covered with a hollow black shielding layer 11a. The black shielding layer 11a completely covers the metal electrodes on the inner surface of the array substrate 11.

The embodiment may be only slightly improved on the traditional liquid crystal panel. A black matrix 12a is arranged in an inner surface of the color film substrate 12, and a projection of the black shielding layer 11a on the color film substrate 12 completely covers the black matrix 12a, i.e., achieving a complete shielding of the metal electrodes. In addition, in order to avoid the viewer from seeing the metal electrodes when viewing from both sides, the black shielding layer 11a of the embodiment completely covers the black matrix 12a and the width of the pattern line is slightly wider than the corresponding part of the black matrix 12a.

As shown in FIG. 2, the display device provided by the disclosure includes a backlight module and the narrow frame display panel. The backlight module is arranged on the side of the color film substrate 12 (as shown in FIG. 2). The backlight module mainly includes a reflection sheet 21, a light guide plate 22, a set of an optical film 23 and a light source 200 from bottom to top, and the light source is arranged on the light guide plate 22 and provides a backlight for the light guide plate 22. A projection of the light source 200 in a direction perpendicular to the direction of the reflection sheet 21 reflection is located in the reflection sheet 21. In this way; the reflection sheet 21 may reflect light emitted by the light source 200 to the maximum extent, thereby improving light utilization and avoiding light leakage near the light guide plate 22.

In the embodiment, the display device may further include a plastic frame 24, a light shielding sheet 25 and a middle frame 26. The light source 200 includes a substrate 201 and LED lamp beads 202 arranged on the surface of the substrate 201. The plastic frame 24 is arranged on the reflection sheet 21 and arranged spaced from the light guide plate. The LED lamp beads 202 are arranged in a gap between the plastic frame 24 and the light guide plate 22, and two ends of the substrate 201 are respectively attached to the upper surface of the light guide plate and the plastic frame. The light-shielding sheet 25 is attached to an upper surface of the substrate 201 and extends to partially cover an edge of the set of an optical film 23, completely preventing the light leakage above a side of light source where the light guide plate is located. A groove 260 is formed in the inner surface of the middle frame 26, the flexible circuit board 14 is directly opposite to the middle frame 26, and the driving chip 15 is housed in the groove 260, so as to further reduce the thickness of the display device and protect the driving chip 15.

The set of an optical film 23 is composed of three optical film layers. The set of an optical film 23 includes a lower prism layer 23a, a diffusion layer 23b and an upper prism layer 23c which are sequentially stacked from bottom to top. A lower surface of the plastic frame 24 is attached on the protruding portion of the reflection sheet 21 by an optical adhesive S1. An upper surface of the plastic frame 24 and an upper surface edge of the light guide plate 22 are respectively adhered with the substrate 201 by another optical adhesive S2. Here, the optical plastic S1, the other optical adhesive S2 are made of light-absorbing material, so as to avoid light leakage there. The light-shielding sheet 25 is attached to an upper surface of the substrate 201 by double-sided adhesive.

In the disclosure, one end of a flexible circuit board is bound to a surface of the bonding end facing the color film substrate, the other end of the flexible circuit board is bound with a driving chip and arranged opposite to the color film substrate after being bent away from the light-exiting surface. Thus the flexible circuit board may not be seen outside the display panel. Therefore, the width of the frame may be reduced and the screen-to-body ratio may be increased. Meanwhile, the driving chip is located on a side of the flexible circuit board facing away from the color film substrate, and therefore may be away from the heated reflection sheet of the backlight module, and this ensures an optical quality without increasing the thickness of the display device. In addition, the black shielding layer on the outer surface of the array substrate may prevent the ambient light from illuminating metal electrodes on the inner surface of the array substrate to prevent specular reflection.

The above descriptions are merely specific embodiments of the present application. It should be noted that those skilled in the art may make some improvements and modifications without departing from the principle of the present application. These improvements and modifications should also be regarded as within the protection scope of this application.

What is claimed is:

1. A narrow frame display panel, comprising an array substrate, a color film substrate, a liquid crystal filled between the array substrate and the color film substrate, a flexible circuit board and a driving chip, wherein a side located by the array substrate is a light-exiting surface, and one end of the array substrate is a bonding end; one end of the flexible circuit board is bound to a surface of the bonding end facing the color film substrate, and the other end of the flexible circuit board is bound with a driving chip and arranged opposite to the color film substrate after being bent away from the light-exiting surface, and the driving chip is located on the side of the flexible circuit board facing away from the color film substrate.

2. The narrow frame display panel according to claim 1, wherein the flexible circuit board is a single-layered chip-on-film, and the bonding end and the driving chip are simultaneously turned on the same side of the single-layered chip-on-film.

3. The narrow frame display panel according to claim 1, wherein an outer surface of the array substrate is covered with a hollow black shielding layer, and the black shielding layer completely shields metal electrodes in an inner surface of the array substrate.

4. The narrow frame display panel according to claim 3, wherein a black matrix is arranged in an inner surface of the color film substrate, and a projection of the black shielding layer on the color film substrate completely covers the black matrix.

5. The narrow frame display panel according to claim 2, wherein an outer surface of the array substrate is covered with a hollow black shielding layer, and the black shielding layer completely shields metal electrodes in an inner surface of the array substrate.

6. The narrow frame display panel according to claim 5, wherein a black matrix is arranged in an inner surface of the color film substrate, and a projection of the black shielding layer on the color film substrate completely covers the black matrix.

7. A display device, comprising a backlight module and a narrow frame display panel, wherein narrow frame display panel comprises an array substrate, a color film substrate, a liquid crystal filled between the array substrate and the color film substrate; a flexible circuit board and a driving chip; wherein a side located by the array substrate is located is a light-exiting surface, and one end of the array substrate is a bonding end; one end of the flexible circuit board is bound to a surface of the bonding end facing the color film substrate, and the other end of the flexible circuit board is bound with a driving chip and arranged opposite to the color film substrate after being bent away from the light-exiting surface, and the driving chip is located on the side of the flexible circuit board facing away from the color film substrate; and the backlight module is arranged on the side of the color film substrate.

8. The display device according to claim 7; wherein the flexible circuit board is a single-layered chip-on-film, and the bonding end and the driving chip are simultaneously turned on the same side of the single-layered chip-on-film.

9. The display device according to claim 7, wherein an outer surface of the array substrate is covered with a hollow black shielding layer; and the black shielding layer completely shields metal electrodes in an inner surface of the array substrate,

10. The display device according to claim 9; wherein a black matrix is arranged in an inner surface of the color film substrate, and a projection of the black shielding layer on the color film substrate completely covers the black matrix.

11. The display device according to claim 7, wherein the backlight module comprises a reflection sheet, a light guide plate, a set of an optical film and a light source from bottom to top, the light source is arranged on the light guide plate and provides a backlight for the light guide plate, and a projection of the light source in a direction perpendicular to the reflection sheet is located in the reflection sheet.

12. The display device according to claim 11, further comprising a plastic frame, the light source comprising a substrate and LED lamp beads arranged on the surface of the substrate; the plastic frame arranged on the reflection sheet and arranged spaced from the light guide plate, wherein the LED lamp beads are arranged in a gap between the plastic frame and the light guide plate, and two ends of the substrate are respectively attached to the upper surface of the light guide plate and the plastic frame.

13. The display device according to claim 9, wherein the backlight module comprises a reflection sheet, a light guide plate, a set of an optical film and a light source from bottom to top, the light source is arranged on the light guide plate and provides a backlight for the light guide plate, and a projection of the light source in a direction perpendicular to the reflection sheet is located in the reflection sheet.

14. The display device according to claim 13, further comprising a plastic frame, the light source comprising a substrate and LED lamp beads arranged on the surface of the substrate, the plastic frame arranged on the reflection sheet and arranged spaced from the light guide plate, wherein the LED lamp beads are arranged in a gap between the plastic frame and the light guide plate, and two ends of the substrate are respectively attached to the upper surface of the light guide plate and the plastic frame.

15. The display device according to claim 8, wherein an outer surface of the array substrate is covered with a hollow black shielding layer, and the black shielding layer completely shields metal electrodes in an inner surface of the array substrate.

16. The display device according to claim 15, wherein a black matrix is arranged in an inner surface of the color film substrate, and a projection of the black shielding layer on the color film substrate completely covers the black matrix.

17. The display device according to claim 12, further comprising a light-shielding sheet, the light-shielding sheet being attached to a upper surface of the substrate and extending to partially cover an edge of the set of an optical film.

18. The display device according to claim 7, further comprising a middle frame, a groove is formed in the inner surface of the middle frame, the flexible circuit board is directly opposite to the middle frame, and the driving chip is housed in the groove.

19. A display device, comprising a backlight module and a narrow frame display panel, wherein narrow frame display panel comprises an array substrate, a color film substrate, a liquid crystal filled between the array substrate and the color film substrate, a flexible circuit board, plastic frame, middle frame and a driving chip, wherein a side located by the array substrate is located is a light-exiting surface, and one end of the array substrate is a bonding end; one end of the flexible circuit board is bound to a surface of the bonding end facing the color film substrate, and the other end of the flexible circuit board is bound with a driving chip and arranged opposite to the color film substrate after being bent away from the light-exiting surface, and the driving chip is located on the side of the flexible circuit board facing away from the color film substrate; and the backlight module is on the side of the color film substrate; the light source comprising a substrate and LED lamp beads arranged on the surface of the substrate, the plastic frame arranged on the reflection sheet and arranged spaced from the light guide plate, wherein the LED lamp beads are arranged in a gap between the plastic frame and the light guide plate, and two ends of the substrate are respectively attached to the upper surface of the light guide plate and the plastic frame; a groove is formed in the inner surface of the middle frame, the flexible circuit board is directly opposite to the middle frame, and the driving chip is housed in the groove.
